(19) United States
(12) Patent Application Publication
(10) Pub. No.: US 2017/0320772 A1
(43) Pub. Date: Nov. 9, 2017

(54) 3D DIFFRACTION COATING PROCESS

(71) Applicant: Xiaoyuan Ma, Shenzhen (CN)

(72) Inventor: Xiaoyuan Ma, Shenzhen (CN)

(21) Appl. No.: 15/149,230

(22) Filed: May 9, 2016

(51) Int. Cl. C03C 17/36; C23C 14/10; C03C 17/34; C03C 17/38; C23C 14/06; C23C 14/08; C23C 14/24; B23K 26/362

(52) U.S. Cl. CPC C03C 17/3657; C23C 14/24; C23C 14/10; C03C 17/3452; C03C 17/3621; C03C 17/3642; C03C 17/3644; C03C 17/3649; C03C 17/38; C23C 14/0694; C23C 14/081; C23C 14/083; C03C 2218/151; C03C 2218/154; C03C 2218/31; C03C 2218/32; B23K 26/362; C03C 2217/72; C03C 2218/112; C03C 2218/115; C03C 2218/33

(57) ABSTRACT

The present invention discloses a 3D diffraction coating process, the operation is simple, due to the principle of newton's rings of single light sources, superimposition of optical wave-wavlet vibration during wave transmission of light and diffraction, refraction, reflection, transmission, transmission increase and reflection increase of the light, slit diffraction generated by a round hole, a rectangular hole and a line in a pattern internally coated in the product is conducted to an outer glass layer to form a diffraction layer, and finally, a muitilayered 3D visual effect is generated, and the manufactured finished product has a good 3D effect, and is very exquisite and high-class.

### BACKGROUND OF THE INVENTION

### Technical Field

The present Invention belongs to the field of glass processing, in particular to a 3D diffraction coating process

### 2. Description of Related Art

Along with the continuous development of optical thin film technology, the application of optical thin film devices is wide increasingly, and temperature stability research on the optical thin film devices also has great importance. Coating is a manufacturing process of depositing an optical thin film onto the surface of an optical part. Optical thin film application, various reflection and projection optical elements, and the thin film echnology are important constituent parts of the optical technology.

The present invention aims to provide a 3D diffraction coating process, the operation is simple, and the prepared finished product ha good 3D effect, is very exquisite and high-class.

### BRIEF SUMMARY OF THE INVENTION

The present invention aims at defects of the prior art and seeks to provide a 3D diffraction coating process and a prepared finished product which has a good 3D effect, is very exquisite and high-class.

The objective of the present invention is realized by the following technical solution:

A 3D diffraction coating process is characterized by comprising the following steps:

(1) Preparing of a Product Blank: Glass

a: die molding and blowing molding of the glass are performed, and the refractive index of the white glass finished product is about 1.56;

b: greasy dirt on the glass and other dirty goods are cleaned with 40 KHZ ultrasonic waves;

c: the glass vapor is baked with a temperature of 65 degrees for 30 minutes.

(2) Processing the Product's Inner Cavity: Internal Electroplating

a: a layer of primer is sprayed onto the product's inner cavity (a: the ratio of paint to diluent is 10: 1-2, b: coupling polymer and composite resin c: the diluent is banana oil) baking temperature is 180 degrees, and duration is 90minutes;

b: internal plating, by using a high voltage electric arc, aluminum and a nickel ion target material are evaporated within a vacuum to be deposited on the surface of the glass, forming a film, thus forming a layer of thin silver film.

c: a layer of finishing coat is sprayed to protect the thin film layer by baking to 160-170 degrees for 90 minutes.

d: the humidity of the workshop is kept below 70%.

(3) Processing the Product's Pictures & Characters: CO2 Lasering of Patterns and Characters

a: platemaking is perform d according to an Al drawing film into the required template

b: CO2 lasering of patterns and characters are performed

c: a CO2 laser machine is used to burn off the coating film according to the platemaking patterns and characters, thus obtaining the desired pattern.

(4) Processing of the External Product: Vacuum Coating of the Optical Plating

a: the vacuum coating is mainly performed under a high vacuum degree and is mainly divided into evaporating and sputtering. Herein, an evaporating coating is used, the material required to be coated is called the substrate, the plated material is called the target material and the substrate and the target material are both in a vacuum cavity:

b: evaporating coating: the target material is heated to evaporate surface components into an atom group or ions and deposited onto the surface of the substrate and a thin film by a film forming process (splattering-island structure-aberration structure-layered growth);

the evaporating coating method comprises: placing ZnS/SiO/ZnS/SiO/ZnS/SiO/ZnS into seven crucibles in sequence, placing about 20 g of evaporating material into each crucible and placing a zirconium and titanium mixture on a molybdenum boat to gasify at high temperature to form a protective layer;

the devices of the vacuum evaporating coating comprise

a: vacuum pump

b: evaporating source

c: main cavity body

d: monitoring system

e: operation system

f: auxiliary device

The target material of the optical vacuum coating is selected from:

a: from chemical constitution, a thin film material is divided into:

oxides: AL2O3, SIO, SIO2, TIO2, TIO3, ZrO2, etc.,

fluorides: MgF2, BaF2, YF3, Na3AlF6, etc.

other compounds: ZnS, ZnSe, PbTe, etc.

b: coating material functions:

an optical dielectric material achieves light transmission function, These materials change the direction, intensity and phase position of the light in refraction, reflection and transmission, so that the light is transmitted according to predetermined requirements, thereby achieving a 3D visual effect.

Due to the principle of Newton's rings of single light sources, superimposition of optical wave-wavlet vibration during wave transmission of light and diffraction, refraction, reflection, transmission, transmission increase, and reflection increase of the light, alit diffraction generated by a round hole, a rectangular hole and a line in a pattern internally coated into the product is conducted to an outer glass layer to form a diffraction layer, and finally, a multilayered 3D visual effect is generated.

The present invention has beneficial effects:

the present invention provides a 3D diffraction coating process, the operation is simple. Due to the principle of newton's rings of single light sources, superimposition of optical wave-wavlet vibration during wave transmission of light and diffraction, refraction, reflection, transmission, transmission increase and reflection increase of the light, slit diffraction generated by a round hole, a rectangular hole and a line in a pattern internally coated into the product is conducted to an outer glass layer to form a diffraction layer, and finally, a multilayered 3D visual effect is generated, and the manufactured finished product has a good 3D effect, and is very exquisite and high-class.

### DETAILED DESCRIPTION OF THE INVENTION

### Embodiment 1

A 3D diffraction coating process is characterized by comprising the following steps:

(1) Preparing of a Product Blank: Glass

a: die molding and blowing molding of the glass are performed, and the refractive index of the white glass finished product is about 1.56;

b: greasy dirt on the glass and other dirty goods are cleaned with 40 KHZ ultrasonic waves;

c: the glass vapor is baked with a temperature of 65 degrees for 30 minutes.

(2) Processing of the Products Inner Cavity: Internal Electroplating

a: a layer of primer is sprayed onto the products inner cavity (a: the ratio of paint to diluent is 10: 1-2, b: coupling polymer and composite resin c: the diluent is banana oil), baking temperature is 180 degrees and duration is 90 minutes.

b: internal plating, by using a high voltage electric arc, aluminum and, a nickel ion target material are evaporated with a vacuum to be deposited on the surface of the glass forming a film, thus forming a layer of thin silver film.

c: a layer of finishing coat is sprayed to protect the thin film layer by baking to 160-170 degrees for 90 minutes.

d: the humidity of the workshop is kept below 70%.

(3) Processing the Products Pictures & Characters: CO2 Lasering of Patterns and Characters

a: a CO2 laser machine is used to burn off the coating film according to the platemaking patterns and characters, thus obtaining the desired pattern.

(4) The Product is Placed in an Isostatic Pressing Device, and the Temperature Rises to 120-140 Degrees and is Preserved for 1-2 h;

(5) Processing of the External Product: Vacuum Coating of the Optical Plating

a: the vacuum coating is mainly performed under a high vacuum degree and is mainly divided into evaporating and sputtering. Herein, an evaporating coating is used, the material required to be coated is called the substrate, the plated material is called the target material and the substrate and the target material are both in a vacuum cavity;

b: evaporating coating: the target material is heated to evaporate the surface components into an atom group or ions and deposited onto the surface of the substrate and a thin film is formed by a film forming process (splattering-island structure-aberration structure-layered growth);

the devices of the vacuum vaporating evaporating coating comprise:

a: vacuum pump

b: evaporating source

c: main cavity, body

d: monitoring system

e: operation system

f: auxiliary device

The target material of the optical vacuum coating is selected from: oxides.

Coating material functions:

an optical dielectric material achieves light transmission function. These materials change the direction, intensity and phase position of the light in refraction, reflection and transmission, so that the light is transmitted according to predetermined requirements, thereby achieving a 3D visual effect,

Due to the principle of newton's rings of single light sources, superimposition of optical wave-wavlet vibration during wave transmission of light and diffraction, refraction, reflection, transmission, transmission increase and reflection increase of the light, slit diffraction generated by a round hole, a rectangular hole and a line in a pattern internally coated in the product is conducted to an outer glass layer to form a diffraction layer, and finally, a multilayered 3D visual effect is generated

Result: the operation is simple, and the manufactured finished product has a good 3D effect, and is very exquisite and high-class.

### Embodiment 2

A 3D diffraction coating process characterized by comprising the following steps:

(1) Preparing of a Product Blank: Glass

a: die molding and blowing molding of the glass are performed, and the refractive index of the white glass finished product is about 1.56;

b: greasy dirt on the glass and other dirty goods are cleaned with 40 KHZ ultrasonic waves;

c: the glass vapor is baked with a temperature of 65 degrees for 30 minutes.

(2) Processing of the Product's Inner Cavity: Internal Electroplating

a: a layer of primer is sprayed onto the product's inner cavity (a: the ratio of paint to diluent is 10: 1-2, b: coupling polymer and composite resin c: the diluent is banana oil) baking temperature is 180 degrees, and duration is 90 minutes;

b: internal plating, by using a high voltage electric arc, aluminum and a nickel ion target material are evaporated within a vacuum to be deposited on the surface of the glass, forming a film, thus forming a layer of thin silver film.

c: a layer of finishing coat is sprayed to protect the thin film layer by baking to 160-170 degrees for 90 minutes.

d: the humidity of the workshop is kept below 70

(3) Processing of the Products Pictures & Characters: CO2 Lasering of Patterns and Characters

a: a CO2 laser machine is used to burn off the coating film according to the platemaking patterns and characters, thus obtaining the desired pattern.

(4) The Product is Placed in an Isostatic Pressing Device, and the Temperature Rises to 120-140 Degrees and is Preserved for 1-2 h;

(5) Processing of the External Product: Vacuum Coating of the Optical Plating

a: the vacuum coating is mainly performed under a high vacuum degree and is mainly divided into evaporating and sputtering. Herein, an evaporating coating is used, the material required to be coated is called the substrate, the plated material is called the target material and the substrate and the target material are both in a vacuum cavity;

b: evaporating coating: the target material is heated to evaporate the surface components into an atom group or ions and deposited onto the surface of the substrate and a thin film is formed by a film forming process (splattering-island structure-aberration structure-layered growth);

the devices of the vacuum evaporating coating comprise:

a: vacuum pump

b: evaporating source

c: main cavity body

d: monitoring system

e: operation system

f: auxiliary device

The target material of the optical vacuum coating is selected from fluorides.

Coating material functions:

an optical dielectric material achieves light transmission function. These materials change the direction, intensity and phase position of the light in refraction, reflection and transmission, so that the light is transmitted according to predetermined requirements, thereby achieving a 3D visual effect.

Due to the principle of Newton's rings of single light sources, superimposition of optical wave-wavlet vibration during wave transmission of light and diffraction, refraction, reflection, transmission, transmission increase and reflection increase of the light, slit diffraction generated by a round hole, a rectangular hole and a line in a pattern internally coated in the product is conducted to an outer glass layer to form a diffraction layer, and finally, a multilayered 3D visual effect is generated

Result: the operation is lira pie, and the manufactured finished product has a good 3D effect, and is very exquisite and high-class.

The above are only preferable specific embodiments, but the protective scope of the present invention is not limited thereto, and equivalent substitutions or changes made by any person of ordinary skill in the art according to the technical solutions and an inventive concept thereof in a technical solution disclosed by the present invention should be covered in the protective scope of the present invention.

1. A 3D diffraction coating process, comprising the following steps:
(1) Preparation a Glass Product Blank
a: performing die molding and blowing molding of the glass wherein the refractive index of the white glass finished product is about 1.56;
b: cleaning greasy dirt on the glass and other dirty goods with 40 KHZ ultrasonic waves;
c: baking the glass vapor at a temperature of 65 degrees for 30 minutes
(2) Processing of the Products Inner Cavity: Internal Electroplating a: spraying a layer of primer onto the products inner cavity at a baking temperature of 180 degrees for a duration of 90 minutes;
b: internal plating, by using a high voltage electric arc, to cause evaporation of aluminum and a nickel ion target material under vacuum and deposition onto the surface of the glass, forming a layer of silver thin film;
c: spraying a layer of finishing coat to protect the thin film layer by baking at 160-170 degrees for 90 minutes;
d: keeping the humidity of the workshop below 70%
(3) Processing of the Product's Pictures & Characters: CO2 Lasering of Patterns and Characters
a: performing platemaking according to an Al drawing film into a required template
b: performing CO₂ lasering of patterns and characters
c: using a CO₂ laser machine to burn off the coating film according to the platemaking patterns and characters, thus obtaining the desired pattern
(4) Processing of the External Product: Vacuum Coating of the Optical Plating
a: performing the vacuum coating under a high vacuum degree, comprising evaporating and sputtering, wherein when an evaporating coating is used the material required to be coated is called the substrate, the plated material is called the target material and the substrate and the target material are both in a vacuum cavity;
b: evaporating coating: heating the target material to evaporate the surface components into an atom group or ions and depositing the target material onto the surface of the substrate, wherein a thin film is formed by a film forming process (splattering-island structure-aberration structure-layered growth); and
the evaporating coating method comprises: placing ZnS/SiO/ZnS/SiO/ZnS/SiO/ZnS into seven crucibles in sequence, placing about 20 g of evaporating material into each crucible and placing a zirconium and titanium mixture on a molybdenum boat to gasify at high temperature to form a protection layer.

2. The 3D diffraction coating process according to claim 1, wherein the devices of the vacuum vaporating coating comprise:
a: vacuum pump
b: evaporating source
c: main cavity body
d: monitoring system
e: operation system
f: auxiliary device

3. The 3D diffraction coating process according to claim 1, wherein the target material of the optical vacuum coating is selected from a group consisting of Al₂O₃, SiO, SiO₂, TiO₂, Ti₂O₃, ZrO₂, MgF₂, BaF₂, YF₃, Na₃AlF₆, ZnS, ZnSe, and PbTe.

4. The 3D diffraction coating process according to claim 1 wherein the primer in step (2) comprising:
a: paint;
b: diluent; and
c: coupling polymer and composite
wherein the ratio of paint to diluent is 10: 1-2 and the diluent is banana oil.
5. 3D diffraction coating glass produced by the 3D diffraction coating process according to claim 1.
